(19) United States
(12) Patent Application Publication
(10) Pub. No.: US 2026/0216894 A1
(43) Pub. Date: Jul. 30, 2026

(54) End Effector with Replaceable Pads

(71) Applicant: Applied Materials, Inc., Santa Clara, CA (US)

(72) Inventor: Daniel McGillicuddy, Peabody, MA (US)

(21) Appl. No.: 19/039,818

(22) Filed: Jan. 29, 2025

(51) Int. Cl. B25J 15/04; H01L 21/687

(52) U.S. Cl. CPC B25J 15/04; H10P 72/7602

(57) ABSTRACT

An end effector that includes replaceable pads is disclosed. The pads may be constructed from a different dielectric material than the end effector. This difference in dielectric material may help reduce particle generation and workpiece damage. Additionally, the pad is attached to the end effector using a latch and a spring, which allows the assembly to remain operational over a wide range of temperatures, even if the end effector and pad have coefficients of thermal expansion that differ by an order of magnitude or more. This assembly may operate to temperatures from −150° C. up to 500° C.

### FIELD

Embodiments of the present disclosure relate to end effectors for use in semiconductor processing systems that include replaceable pads.

### BACKGROUND

Ion implanter systems often utilize an ion source to generate ions. One wall of the ion source is referred to as an extraction plate and includes an extraction aperture. One or more electrodes are disposed outside the extraction aperture. At least one of the electrodes is biased at a negative voltage relative to the ion source to attract positive ions from the ion source through the extraction aperture.

These ions may pass through one or more components to reach the workpiece, which is typically mounted on a platen. Workpieces are placed and removed from the platen using a robot having an end effector. The end effector may have a plurality of raised bumps, also referred to as pads. The workpiece rests on these pads as it is being moved to and from the platen.

These pads are an integral part of the end effector, and are therefore made from the same material as the rest of the end effector. However, the characteristics that are beneficial for the end effector, such as stiffness and long life, may not be best for the pads, which contact the workpiece.

Therefore, a system that allows the pads to be constructed from a different material than the rest of the end effector would be beneficial. Further, it would be advantageous if this system operated over a wide range of temperatures.

### SUMMARY

An end effector that includes replaceable pads is disclosed. The pads may be constructed from a different dielectric material than the end effector. This difference in dielectric material may help reduce particle generation and workpiece damage. Additionally, the pad is attached to the end effector using a latch and a spring, which allows the assembly to remain operational over a wide range of temperatures, even if the end effector and pad have coefficients of thermal expansion that differ by an order of magnitude or more. This assembly may operate to temperatures from −150° C. up to 500° C.

According to one embodiment, an end effector for use in a semiconductor processing system is disclosed. The end effector comprises an arm made of a first material and having a plurality of openings; a plurality of pads, made from a second material, each pad disposed in a respective opening; wherein each pad comprises a rounded head and a shaft that passes through the respective opening, the shaft having a first shaft portion attached to the rounded head, and a second shaft portion at a distal end of the shaft; a latch to engage with the second shaft portion to lock the pad in place; and a spring disposed between the rounded head and the latch to apply tension to the pad and allow for thermal expansion and contraction of the pads. In some embodiments, the spring is disposed between an underside of the arm and the latch. In some embodiments, the spring is disposed between the rounded head and a top surface of the arm. In some embodiments, the first shaft portion has a circular cross-section and the second shaft portion has a cross-section that is not circular, and wherein the latch includes an opening having a same shape as the cross-section of the second shaft portion. In certain embodiments, the shaft comprises a third shaft portion between the first shaft portion and the second shaft portion, wherein, in a locked position, the latch is positioned in the third shaft portion and is pressed by the spring against a top of the second shaft portion. In certain embodiments, the second shaft portion has a cross-section that is longer in a first dimension than a second dimension. In some embodiments, in a locked position, the latch is pressed by the spring against a top of the second shaft portion, and wherein notches are located on a bottom side of the latch, such that the second shaft portion rests in the notches when in the locked position. In some embodiments, the first material and the second material comprise dielectric materials. In some embodiments, the first material comprises quartz glass. In some embodiments, the second material is different from the first material. In certain embodiments, the second material comprises graphite, silicon carbide, silicon, sapphire, alumina or zirconia.

According to another embodiment, a semiconductor processing system is disclosed. The semiconductor processing system comprises a workpiece handling apparatus, the workpiece handling apparatus comprising any of the end effectors described above.

According to another embodiment, a method for replacing pads located on an end effector disposed in a semiconductor processing system is disclosed. The method comprises rotating a latch used to secure a pad to an arm of the end effector, such that the latch moves from a locked position to an unlocked position; detaching the latch from the pad; removing the pad from the arm of the end effector; placing a new pad in an opening in the arm of the end effector; sliding the latch over a shaft of the new pad; and rotating the latch from the unlocked position to the locked position. In some embodiments, the method comprises installing a spring over the shaft of the new pad before sliding the latch over the shaft. In certain embodiments, the spring is disposed between an underside of the arm of the end effector and the latch. In some embodiments, the pad is made from a second material different from a first dielectric material used for the arm of the end effector. In certain embodiments, the second material is selected to reduce particle generation and damage to a workpiece disposed on the pads. In certain embodiments, the second material is a dielectric material. In some embodiments, the pads are replaced when a preventative maintenance is performed on the semiconductor processing system. In some embodiments, a distal end of the shaft has a cross-section having a non-circular shape, and an inner opening in the latch has a similar non-circular shape, wherein the inner opening is aligned with the distal end of the shaft when in the unlocked position such that the latch is slid along the shaft.

### BRIEF DESCRIPTION OF THE FIGURES

For a better understanding of the present disclosure, reference is made to the accompanying drawings, which are incorporated herein by reference and in which:

FIG. 1 is a lift assembly that includes an end effector having replaceable pads according to one embodiment;

FIG. 2 is an expanded view of the end effector of FIG. 1;

FIGS. 3A-3B are a view of the pad and the latch, respectively;

FIG. 4 is an expanded view of an arm of the end effector of FIG. 2;

FIGS. 5A-5B show the latch in the unlocked and locked positions, respectively;

FIG. 6 shows the pad installed and locked into the end effector; and

FIG. 7 is a workpiece processing apparatus that may use the improved end effector.

### DETAILED DESCRIPTION

This disclosure describes a mechanism that allows the pads of an end effector to be made of a different material than the rest of the end effector. Advantageously, this mechanism is operable over a wide range of temperatures.

In one embodiment, the disclosure describes a lift assembly that includes an end effector with replaceable pads. This lift assembly may be used as part of a workpiece handling apparatus that may be disposed in a process chamber, along with a platen on which the workpiece is disposed during processing. This workpiece handling apparatus may be used with a semiconductor processing system, such as an ion implantation system, etching system or deposition system.

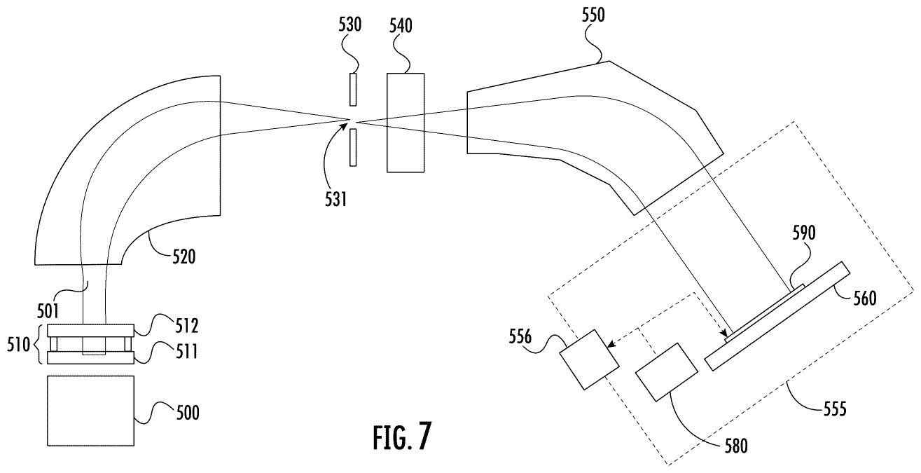

One such semiconductor processing system is shown in FIG. 7. The semiconductor processing system may include an ion source 500, which is used to generate an ion beam. The ion source 500 may be an indirectly heated cathode (IHC) ion source, a capacitively coupled plasma source, an inductively coupled plasma source, or a different source. Disposed outside and proximate the extraction aperture of the ion source 500 are extraction optics 510. In certain embodiments, the extraction optics 510 comprise one or more electrodes, including extraction electrode 511. In certain embodiments, the extraction optics 510 may comprise a second electrode 512 which may be biased at a different voltage than extraction electrode 511. In some embodiments, in excess of two electrodes, such as three electrodes or four electrodes, may be employed. In these embodiments, the electrodes may be functionally and structurally similar to those described above, but may be biased at different voltages. These electrodes may each be mounted to a mounting flange. In other embodiments, one or more of these electrodes may be movable in one or more directions. To facilitate this movement, one or more of the electrodes may be connected to a manipulator, which moves the associated electrode in one or more directions.

Located downstream from the extraction optics 510 is a mass analyzer 520. The mass analyzer 520 uses magnetic fields to guide the path of the extracted ions 501. The magnetic fields affect the flight path of ions according to their mass and charge. A mass resolving device 530 that has a resolving aperture 531 is disposed at the output, or distal end, of the mass analyzer 520. By proper selection of the magnetic fields, only those extracted ions 501 that have a selected mass and charge will be directed through the resolving aperture 531. Other ions will strike the mass resolving device 530 or a wall of the mass analyzer 520 and will not travel any further in the system.

One or more beamline components may be disposed downstream from the mass resolving device 530. For example, a collimator 540 may be disposed downstream from the mass resolving device 530. The collimator 540 accepts the extracted ions 501 that pass through the resolving aperture 531 and creates a ribbon ion beam formed of a plurality of parallel or nearly parallel beamlets. In other embodiments, the ion beam may be a spot beam. In this embodiment, an electrostatic scanner may be disposed downstream from the mass resolving device 530 and may be used to move the spot beam in a first direction, as defined below.

Located downstream from the collimator 540 may be an acceleration/deceleration stage 550. The acceleration/deceleration stage 550 may be an electrostatic filter. The electrostatic filter is a beam-line lens component configured to independently control deflection, deceleration, and focus of the ion beam. The acceleration/deceleration stage 550 may comprise a plurality of electrodes, in the form of electrically biased rods, that are used to manipulate the ion beam. The output from the acceleration/deceleration stage 550 may be a ribbon ion beam having a width in the first direction, which is much greater than its height in the second direction. Located downstream from the acceleration/deceleration stage 550 is the platen 560.

The ion beam enters a process chamber 555. The process chamber 555 may include a load lock 556 that is used to move workpieces from an atmospheric environment to the vacuum conditions within the process chamber 555. In some embodiments, this is achieved using a sealed volume having two doors, a first door in communication with the atmospheric environment and a second door in communication with the process chamber 555. When transferring a workpiece to the process chamber 555, the first door is opened, the workpiece is placed in the load lock 556, and the first door is closed. The load lock 556 is then pumped down to vacuum conditions and then the second door is opened, allowing the workpiece to be removed by a workpiece handling apparatus 580. When the workpiece has been processed, the process is repeated in the reverse order. In some embodiments, the load lock 556 is static. In other embodiments, the first door and the second door may be at different elevations. In this case, an elevator shaft may be used to move the load lock between the two elevations.

Within the process chamber 555 may be one or more workpiece handling apparatus 580, which are used to transfer the workpiece from the load lock 556 to the platen 560. The workpiece handling apparatus 580 may include an end effector to lift, move and place the workpiece. Additionally, the workpiece handling apparatus 580 may be used to move the workpiece to other stations located within the process chamber 555, such as a heating or cooling station, or an alignment station.

Note that, in some embodiments, one or more workpiece handling apparatus 580 may also be disposed outside the process chamber 555. These apparatus may be used to move the workpiece from the load lock to another station.

The workpiece 590, which may be, for example, a silicon wafer, a silicon carbide wafer, a gallium nitride wafer, or another semiconductor substrate, is disposed on the platen 560. The platen 560 may be moved in the second direction, which is perpendicular to the first direction, to allow the entirety of the workpiece 590 to be processed by the ion beam.

The system of FIG. 7 may be modified. For example, in another embodiment, the ion source 500 is disposed within or adjacent to the process chamber 555 and the beamline components may not be present. Further, in this configuration, the platen 560 may be electrically biased to attract ions directly from within the ion source 500. In these embodiments, the load lock 556 and the workpiece handling apparatus 580 described above may be employed.

Further, while FIG. 7 shows a beamline system for ion implantation, it is understood that there are other types of semiconductor processing systems, such as etching systems, deposition tools, chemical mechanical planarization tools, cluster tools and others that employ similar load lock, platen and/or workpiece handling apparatus as described above.

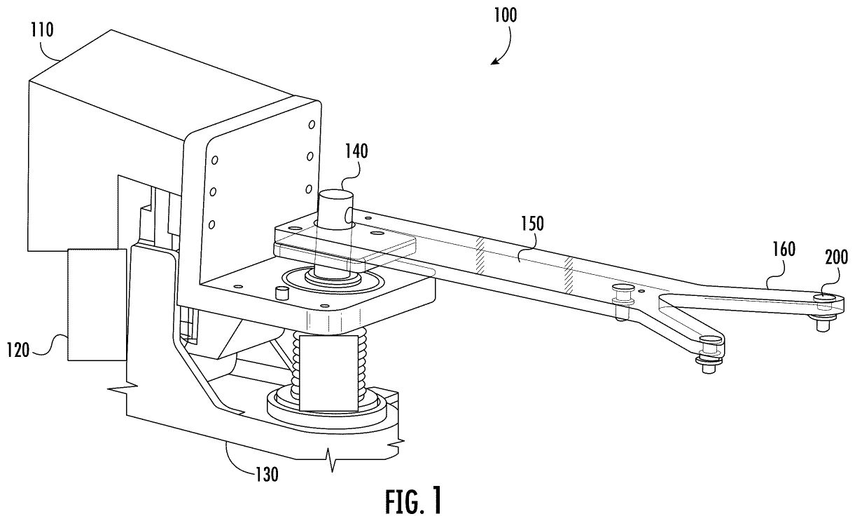

FIG. 1 shows one embodiment of a lift assembly 100 that includes an end effector 150 with replaceable pads 200. The lift assembly 100 may be part of the workpiece handling apparatus 580 and includes a mounting bracket 110, which remains stationary. A motor 120, in the form of a linear actuator, is attached to a lift shaft bracket 130. The actuation of the motor 120 allows the lift shaft bracket 130 to move in the vertical direction relative to the mounting bracket 110. Disposed on top of the lift shaft bracket 130 is a lift shaft 140. The distal end of the lift shaft 140 is coupled to the proximal end of an end effector 150. The lift shaft 140 is held in place by the mounting bracket 110. As noted above, the end effector 150 is used to pick up and place workpieces on the platen 560 or other stations.

The actuation of the motor 120 causes the lift shaft bracket 130 to move in the vertical direction, moving the lift shaft 140 in an up-and-down direction, which in turn moves the end effector 150.

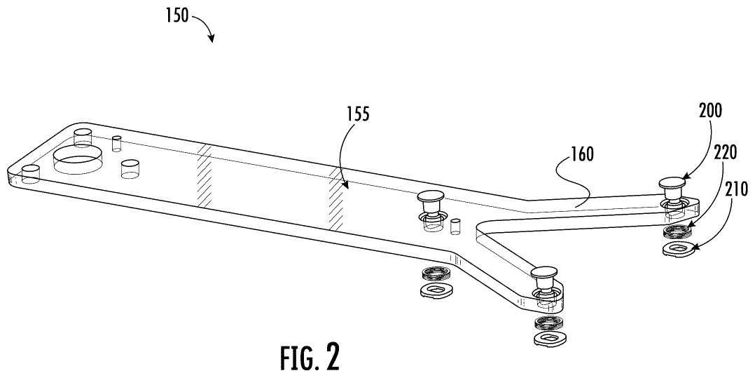

As best seen in FIG. 2, the end effector 150 may include an arm 155, which may have one or more prongs 160 at its distal end. The arm 155 of the end effector 150 is typically made from a first dielectric material, such as quartz glass. This first dielectric material is selected due to its hardness and durability. This first dielectric material may have a first coefficient of thermal expansion (CTE). If quartz glass is used, this first CTE may be very low, such as 5.0×10⁻⁷/° C.

Located on the top surface of the arm 155 of the end effector 150 are two or more pads 200. These pads 200 may be manufactured using a second material, which is different from the first dielectric material. In some embodiments, the second material is a dielectric material. In some embodiments, this second material may be graphite, silicon carbide, silicon, sapphire, alumina or zirconia, although other materials may be used. These second materials have a CTE that may be an order of magnitude greater than that of the first CTE. Thus, the pad 200 may expand more than the end effector 150 as the temperature of the environment is increased or when a hot workpiece is placed on the end effector 150.

The pad 200 is held in place using a latch 210, which is located on the bottom side of the arm 155 of the end effector 150. The latch 210 may be made of the same material as the pad 200. In other embodiments, the latch 210 may be made from a different dielectric material. For example, in some systems, the latch 210 may be exposed to light or another electromagnetic energy for heating and a different dielectric material may be used which absorbs less heat than the dielectric material used for the pad 200. The latching mechanism between the pad 200 and the latch 210 is described in more detail below.

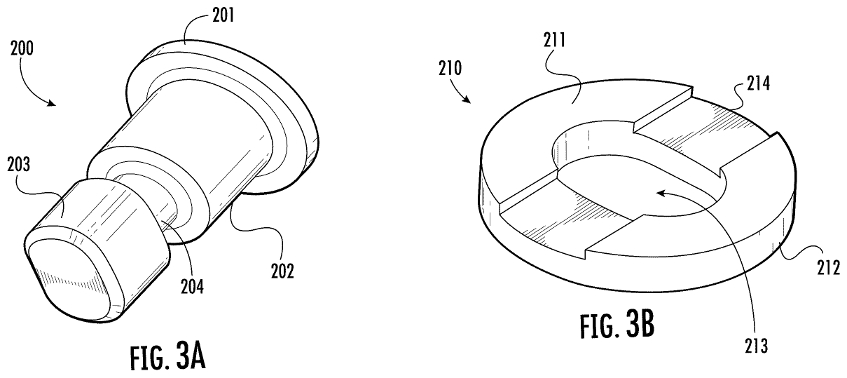

As the temperature of the environment increases, the pad 200 may expand along its shaft, also referred to as its central axis. Its rate of expansion may be greater than the expansion of the end effector 150, which may cause the gap between the bottom surface of the arm 155 of the end effector 150 and the latch 210 to increase. To address this thermal expansion, a spring 220 is disposed between the underside of the arm 155 and the top surface 212 (see FIG. 3B) of the latch 210. This spring 220 may be made from a stainless steel alloy that has high strength and corrosion resistance over a wide range of temperatures. One such alloy may be A286, although other materials may also be used. Note that in another embodiment, the spring 220 may be located between the rounded head of the pad 200 and the top surface of the arm 155. Thus, in both embodiments, the spring 220 is located between the rounded head of the pad 200 and the latch 210, and is pressed against one surface of the arm 155 of the end effector 150.

Note as well that as the temperature decreases, the pad 200 may contract along the central axis at a faster rate than the contraction of the end effector 150, which may cause the gap between the bottom surface of the arm 155 of the end effector 150 and the latch 210 to decrease. Again, the spring 220 may be used to compensate for this thermal contraction.

FIGS. 3A-3B show the pad 200, and the latch 210, respectively, in more detail. The pad 200 includes a rounded head 201 attached to a shaft having a proximal end attached to the rounded head 201 and a distal end. The rounded head 201 is circular with a dome shaped top surface on which the workpiece rests. A first shaft portion 202 extends downward from the rounded head 201. This first shaft portion 202 may have a circular cross-section, where the cross-section is taken along a plane perpendicular to the central axis of the shaft. The cross-section of the first shaft portion 202 has a smaller diameter than the rounded head 201. The length of the first shaft portion 202 may be greater than the thickness of the arm 155 of the end effector 150. A second shaft portion 203 may be disposed at the distal end of the shaft. The cross-section of the second shaft portion is not circular; rather, it is an asymmetric shape such that a first dimension may be greater than the perpendicular second dimension. Its first dimension may be the same as the diameter of the first shaft portion 202. As an example, this second shaft portion 203 may be oval, rectangular or elliptical in shape. A third shaft portion 204 may be disposed between the first shaft portion 202 and the second shaft portion 203. The cross-section of the third shaft portion 204 may be circular, with a diameter that may be smaller than or equal to that of the first shaft portion 202. The diameter may be the same size or smaller than the second dimension of the second shaft portion 203. The length of the third shaft portion 204 may be greater than the thickness of the latch 210.

FIG. 3B shows the latch 210 in more detail. This is a view of the bottom side 211, which, when installed, is further from the arm 155 of the end effector 150 than the top surface 212. The outer surface of the latch 210 may be round, or may be oval to accommodate the spring 220, although other shapes may be utilized. The inner opening 213 has the same shape as the cross-section of the second shaft portion 203 of the pad 200. The inner opening 213 may be dimensioned slightly larger than the second shaft portion 203 to ensure there is no friction when the latch 210 is being attached. The bottom side 211 of the latch 210 may include notches 214. These notches 214 may be dimensioned such that the second shaft portion 203 rests in the notches 214 when in the locked position.

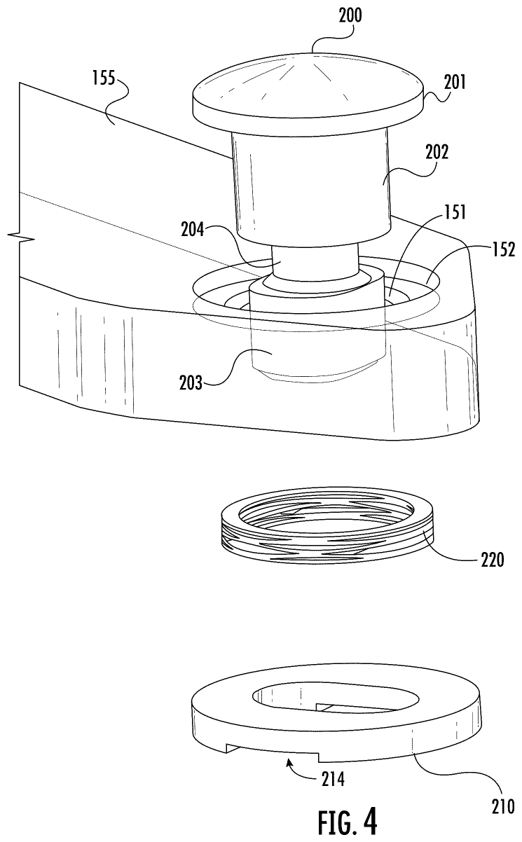

FIG. 4 shows an expanded view of the arm 155 of FIG. 2. Openings 151 are disposed through the arm 155 of the end effector 150. These openings 151 have a diameter that is at least as large as the outer diameter of the first shaft portion 202 but smaller than the diameter of the rounded head 201. In this way, the pad 200 passes through the opening 151 and only the rounded head 201 remains on the top surface of the arm 155. In some embodiments, the openings 151 are countersunk to create annular ledges 152 which support the rounded head 201 of the pad 200. In other embodiments, the rounded head 201 rests on the top surface of the arm 155 of the end effector 150.

The inner diameter of the spring 220 is at least as large as the diameter of the first shaft portion 202 such that the shaft of the pad 200 passes through the spring 220. In this embodiment, the spring 220 is disposed between the underside of the arm 155 of the end effector 150 and the latch 210. The latch 210 is disposed such that the bottom side 211 with the notches 214 is facing away from the arm 155.

Note that other variations of the pad 200 and the latch 210 may be used. For example, the cross-section of the second shaft portion 203 may be any shape, other than circular, with the inner opening 213 of the latch 210 having a similar shape. For example, the cross-section may be triangular, square, or any other polygonal shape. For these shapes, the amount of rotation to lock the latch to the pad 200 may not be 90°. For example, for a triangle, the rotation may be 60°, while for a square, it may be 45°.

Further, in certain embodiments, there may not be a third shaft portion 204. Rather, the diameter of the first shaft portion 202 may be smaller than that of the opening 151.

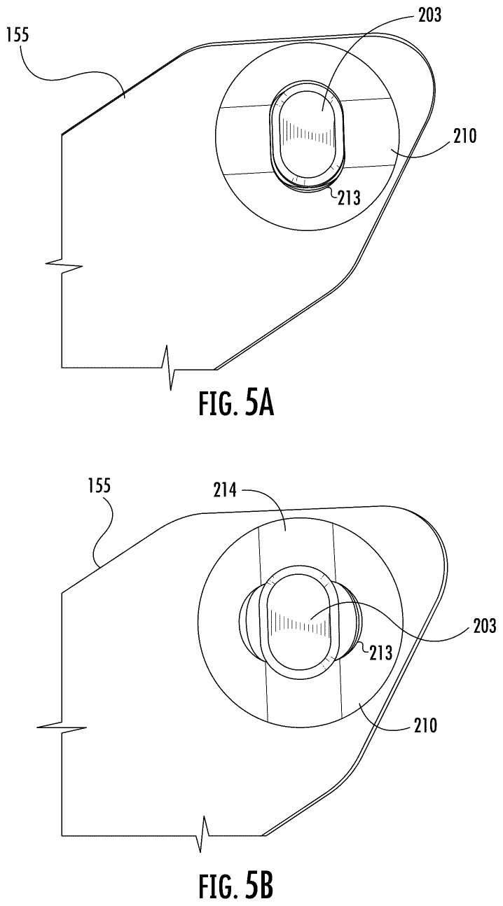

FIGS. 5A-5B show the process of locking the pad 200 with the latch 210. As shown in FIG. 5A, to lock the pad 200 in place, the latch 210 is aligned such that the inner opening 213 is aligned with the second shaft portion 203 of the pad 200. The latch 210 is then pressed toward the arm 155 of the end effector 150 such that the latch 210 slides past the second shaft portion 203 and reaches the third shaft portion 204.

Once the latch 210 passes the second shaft portion 203, the latch 210 and the pad 200 are rotated with respect to one another by an amount to lock the latch 210 in place. If the second shaft portion 203 has an oval shaped cross-section, the latch 210 and the pad 200 are rotated with respect to each other by 90°, as shown in FIG. 5B. The smaller dimension of the inner opening 213 is now aligned with the larger dimension of the second shaft portion 203. Further, the top of the second shaft portion 203 may rest within the notches 214 on the bottom side 211 of the latch 210 to hold the pad 200 in place.

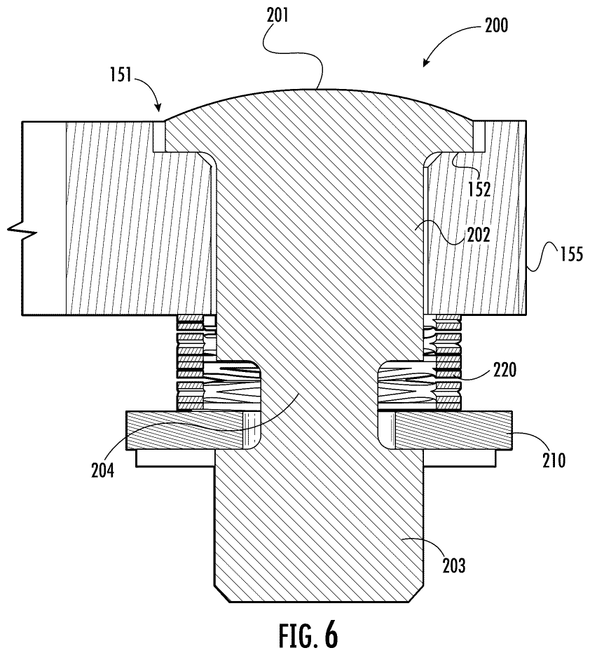

FIG. 6 shows the pad 200 installed in the arm 155 of the end effector 150 when in the locked position. Note that the spring 220 provides the tension to force the rounded head 201 of the pad 200 against the annular ledge 152. Further, the latch 210 is pressed against the top of the second shaft portion 203.

The embodiments described above in the present application may have many advantages. First, the end effector 150 is typically made from a durable material, such as quartz glass. However, this material, when used for the pads, may cause damage to the bottom side of the workpiece. Thus, the present disclosure allows the pads to be made using a softer dielectric or other material that may cause less damage to the workpiece. Additionally, the use of a different dielectric or other material may reduce the generation of particles, which causes fewer defects. Further, the different dielectric or other material used for the pads may also reduce workpiece slippage, as compared to the material used for the end effector.

Second, the pads are easily replaceable by rotating the latch 210 and removing the pad 200. Thus, soft pads are easily changed, cause little down time and are very inexpensive. Thus, during scheduled preventative maintenance (PM) operations, it may be desirable to replace the pads 200. This effectively “cleans” the pads. Further, if unacceptable levels of particles are detected, the pads 200 may be replaced without having to disassemble the lift assembly.

Third, the use of a spring between the arm 155 of the end effector 150 and the latch 210 allows for thermal expansion and contraction. Thus, even if the shaft of the pad 200 expands and contracts at a different rate than the end effector 150, the spring 220 is able to maintain the desired tension. Thus, this assembly remains operational over a wide range of temperatures, such as between −150° C. and 500° C.

The present disclosure is not to be limited in scope by the specific embodiments described herein. Indeed, other various embodiments of and modifications to the present disclosure, in addition to those described herein, will be apparent to those of ordinary skill in the art from the foregoing description and accompanying drawings. Thus, such other embodiments and modifications are intended to fall within the scope of the present disclosure. Furthermore, although the present disclosure has been described herein in the context of a particular implementation in a particular environment for a particular purpose, those of ordinary skill in the art will recognize that its usefulness is not limited thereto and that the present disclosure may be beneficially implemented in any number of environments for any number of purposes. Accordingly, the claims set forth below should be construed in view of the full breadth and spirit of the present disclosure as described herein.

What is claimed is:

1. An end effector for use in a semiconductor processing system, comprising:
an arm made of a first material and having a plurality of openings;
a plurality of pads, made from a second material, each pad disposed in a respective opening;
wherein each pad comprises a rounded head and a shaft that passes through the respective opening, the shaft having a first shaft portion attached to the rounded head, and a second shaft portion at a distal end of the shaft;
a latch to engage with the second shaft portion to lock the pad in place; and
a spring disposed between the rounded head and the latch to apply tension to the pad and allow for thermal expansion and contraction of the pads.

2. The end effector of claim 1, wherein the spring is disposed between an underside of the arm and the latch.

3. The end effector of claim 1, wherein the spring is disposed between the rounded head and a top surface of the arm.

4. The end effector of claim 1, wherein the first shaft portion has a circular cross-section and the second shaft portion has a cross-section that is not circular, and wherein the latch includes an opening having a same shape as the cross-section of the second shaft portion.

5. The end effector of claim 4, wherein the shaft comprises a third shaft portion between the first shaft portion and the second shaft portion, wherein, in a locked position, the latch is positioned in the third shaft portion and is pressed by the spring against a top of the second shaft portion.

6. The end effector of claim 4, wherein the second shaft portion has a cross-section that is longer in a first dimension than a second dimension.

7. The end effector of claim 1, wherein in a locked position, the latch is pressed by the spring against a top of the second shaft portion, and wherein notches are located on a bottom side of the latch, such that the second shaft portion rests in the notches when in the locked position.

8. The end effector of claim 1, wherein the first material and the second material comprise dielectric materials.

9. The end effector of claim 1, wherein the first material comprises quartz glass.

10. The end effector of claim 1, wherein the second material is different from the first material.

11. The end effector of claim 10, wherein the second material comprises graphite, silicon carbide, silicon, sapphire, alumina or zirconia.

12. A semiconductor processing system comprising a workpiece handling apparatus, the workpiece handling apparatus comprising the end effector of claim 1.

13. A method for replacing pads located on an end effector disposed in a semiconductor processing system, the method comprising:
rotating a latch used to secure a pad to an arm of the end effector, such that the latch moves from a locked position to an unlocked position;
detaching the latch from the pad;
removing the pad from the arm of the end effector;
placing a new pad in an opening in the arm of the end effector;
sliding the latch over a shaft of the new pad; and
rotating the latch from the unlocked position to the locked position.

14. The method of claim 13, further comprising:
installing a spring over the shaft of the new pad before sliding the latch over the shaft.

15. The method of claim 14, wherein the spring is disposed between an underside of the arm of the end effector and the latch.

16. The method of claim 13, wherein the pad is made from a second material different from a first dielectric material used for the arm of the end effector.

17. The method of claim 16, wherein the second material is selected to reduce particle generation and damage to a workpiece disposed on the pads.

18. The method of claim 16, wherein the second material is a dielectric material.

19. The method of claim 13, wherein the pads are replaced when a preventative maintenance is performed on the semiconductor processing system.

20. The method of claim 13, wherein a distal end of the shaft has a cross-section having a non-circular shape, and an inner opening in the latch has a similar non-circular shape, wherein the inner opening is aligned with the distal end of the shaft when in the unlocked position such that the latch is slid along the shaft.
